(19) United States
(12) Patent Application Publication
(10) Pub. No.: US 2024/0421597 A1
(43) Pub. Date: Dec. 19, 2024

(54) APPARATUS AND ISLANDING DETERMINATION METHOD IN DISTURBANCE AND DISTORTION SYSTEM

(71) Applicant: HYUNDAI MOBIS CO., LTD., Seoul (KR)

(72) Inventors: Seung Min HONG, Suwon-si (KR); Hyeong Su KIM, Hwaseong-si (KR)

(73) Assignee: HYUNDAI MOBIS CO., LTD., Seoul (KR)

(21) Appl. No.: 18/593,006

(22) Filed: Mar. 1, 2024

(30) Foreign Application Priority Data
Jun. 13, 2023 (KR) 10-2023-0075487

(51) Int. Cl. H02J 3/00; H02J 3/18; H02J 3/38

(52) U.S. Cl. CPC H02J 3/0012; H02J 3/18; H02J 3/388

(57) ABSTRACT

Apparatus and method for determining islanding of a system are provided. The method includes: calculating an amount of reactive power injection based on an active power command and reactive power command received from an upper controller of the distributed power; setting a failure confirmation count to 0; controlling injection of reactive power during a preset cycle among predetermined cycles of an AC voltage that is an output of the distributed power according to the failure confirmation count; measuring a frequency and angular frequency of the AC voltage, which is performed simultaneously with the injection of reactive power; and after the injection of reactive power is completed, increasing the failure confirmation count if a determination criteria based on the measurement of the frequency and the angular frequency of the AC voltage; and determining an islanding failure when the failure confirmation count reaches a preset value.

### CROSS-REFERENCE TO RELATED APPLICATION(S)

The present application claims priority to Korean Patent Application No. 10-2023-0075487, filed Jun. 13, 2023, the entire disclosures of which is incorporated herein for all purposes by this reference.

### BACKGROUND

### 1. Field

The disclosure relates to an islanding determination method in a disturbance and distortion system, and more specifically, to an islanding determination method that does not cause false detection even in a section where harmonics exist in the system.

### 2. Description of Related Art

When a distributed power operates in conjunction with a power system, a failure occurs in the power system. When the power system is separated and the distributed power supplies power to a load independently, it is called islanding. In order to quickly identify power system failures, it is necessary to quickly detect whether distributed power is operated in islanding mode and stop the islanding.

In general, a passive or active method is used to detect the islanding of distributed power.

The passive method measures voltage, current, and frequency in a system where distributed power are connected and determines whether or not distributed power is operated in islanding mode based on whether or not the power system is separated. Although the passive method is simple to implement and has excellent speed, there is a non-detection zone (NDZ) in which islanding cannot be determined when a change in values measured when disconnecting the system is small, and it is susceptible to sudden load changes in normal operation. Also, there is a disadvantage in that detection performance is poor when multiple distributed powers are applied.

In the active method, minute disturbance elements (e.g., reactive power) are injected into the connecting lines of the power system and changes in voltage/current or frequency due to this disturbance signal are detected, and whether distributed power is operated in islanding mode is determined based on whether or not the power system is separated. This conventional active method has the problem of lacking an equation and detailed determination logic for calculating an injection amount of reactive power, and in a system where disturbance and distortion exist, there is problems such as false detection of islanding.

### SUMMARY

The disclosure has been created to solve the problems described above, and an object of the disclosure is to provide a method for determining islanding in a disturbance and distortion system comprising a specific equation and determination process for injecting reactive power as an islanding determination method, and providing an islanding determination method in a disturbance and distortion system that does not cause false detection even in sections where disturbances and distortions, i.e., harmonics, exist in the system.

In a general aspect of the disclosure, a method for determining islanding of a system in which a grid and distributed power supply power to a load, includes the steps of: a) calculating an amount of reactive power injection based on an active power command and reactive power command received from an upper controller of the distributed power, and setting a failure confirmation count to 0; b) injecting reactive power during a preset cycle among predetermined cycles of an AC voltage that is an output of the distributed power according to the failure confirmation count; c) measuring a frequency and angular frequency of the AC voltage, which is performed simultaneously with the step b); d), after the step b) is completed, increasing the failure confirmation count if a determination criteria based on the frequency and angular frequency measured in the step c) is satisfied; and e), after the step d) is performed, determining an islanding failure when the failure confirmation count reaches a preset value, wherein the step b), the step c), the step d), and the step e) are repeatedly performed until the islanding failure is confirmed in the step e).

The step a) may include the steps of: a-1) receiving the active power command and reactive power command from the upper controller, measuring an instantaneous value of the AC voltage at a connection point between the grid and the distributed power using a voltage measurement circuit included in the distributed power, and calculating an effective value and frequency of the AC voltage using the instantaneous value; a-2) calculating a resistance value of the load using active power output from the distributed power; a-3) calculating an inductor value and capacitor value of the load using a preset power quality coefficient; and a-4) determining the amount of the reactive power injection using the effective value of the AC voltage, the inductor value, the capacitor value, and a magnitude of injection frequency.

In the step a-1), the effective value and frequency of the AC voltage may be repeatedly calculated at regular cycles using the instantaneous value.

In the step a-4), the amount of the reactive power injection is calculated using an equation below:

$${Q}_{inj} = {V}_{rms}^{2} * ( \frac{1}{2 π {f}_{inj} {L}_{load}} - 2 π {f}_{inj} {C}_{load} )$$

where, Qᵢₙⱼ is the amount of the reactive power injection, Vᵣₘₛ is the effective value of the AC voltage, fᵢₙⱼ is the magnitude of the injection frequency, L_{load} is the inductor value of the load, and C_{load} is the capacitor value of the load.

The step a-4) may determine the magnitude of the injection frequency using an equation below:

$${f}_{inj} = {f}_{grid} + Δ {f}_{inj} - {Q}_{acc} * {Q}_{rated} < {Q}_{inf} < + {Q}_{acc} * {Q}_{rated} \\ {f}_{grid} = 2 π \frac{1}{\sqrt{{L}_{load} {C}_{load}}}$$

where, f_{grid} is a frequency of the grid, Δf ᵢₙⱼ is an increment of the injection frequency, Q_{acc} is a preset reactive power accuracy, and Q_{rated} is a rated reactive power of the distributed power.

In the step b), the reactive power may be injected during m cycles among n cycles of the AC voltage, and as the failure confirmation count increases, the m and the n may be changed so that a value obtained by dividing the m by the n increases.

In the step b), when the failure confirmation count is 0, the reactive power may be injected for 3 cycles out of 8 cycles of the AC voltage, when the failure confirmation count is 1, the reactive power may be injected for 3 cycles out of 5 cycles of the AC voltage, and when the failure confirmation count is 2, the reactive power may be injected during 4 cycles out of 5 cycles of the AC voltage.

The step e) may include confirming the islanding failure when the failure confirmation count is 3.

In the step b), the reactive power may be alternately injected in plus and minus directions.

In the step c), the angular frequency may be measured by measuring an output of PLL included in the distributed power.

In the step b), the reactive power may be injected during a first section in which the reactive power linearly increases, a second section in which the reactive power is maintained, and a third section in which the reactive power linearly decreases, and in the step c), when the failure confirmation count is 0 or 1, the frequency may be measured at three time points in the second section, and the angular frequency may be measured at first and last time points among the three time points.

In the step d), if all of determination criteria below are satisfied, the failure confirmation count may be increased using an equation below:

$$\vert {ω}_{1} - {ω}_{3} \vert \geq \vert 2 πΔ {f}_{inj} \vert \\ ( {f}_{1} < {f}_{2} < {f}_{3} ) ‖ ( {f}_{1} > {f}_{2} > {f}_{3} )$$

where, ω₁ is the angular frequency measured at the first time point of the three time points, ω₃ is the angular frequency measured at the last time point among the three time points, f₁, f₂, f₃ are the frequencies measured sequentially at the three time points, and Δfᵢₙⱼ is an increment of the injection frequency.

In the step b), the reactive power may be injected during a first section in which the reactive power linearly increases, a second section in which the reactive power is maintained, and a third section in which the reactive power linearly decreases, and in the step c), when the failure confirmation count is 2, the frequency may be measured at four time points in the second section, and the angular frequency may be measured at first and last time points of the four time points, using an equation below:

$$\vert {ω}_{1} - {ω}_{4} \vert \geq \vert 2 π Δ {f}_{inj} \vert \\ ( {f}_{1} < {f}_{2} < {f}_{3} < {f}_{4} ) ‖ ( {f}_{1} > {f}_{2} > {f}_{3} > {f}_{4} ) \\ \vert {f}_{1} - {f}_{4} \vert \geq Δ {f}_{inj}$$

where ω₁ is the angular frequency measured at the first time point of the four time points, ω₄ is the angular frequency measured at the last time point among the four time points, f₁, f₂, f₃, f₄ are the frequencies measured sequentially at the four time points, and Δfᵢₙⱼ is an increment of the injection frequency.

In another general aspect of the disclosure, an apparatus for determining islanding of a system in which a grid and distributed power supply power to a load, includes: a processor configured to: calculate an amount of reactive power injection based on an active power command and reactive power command received from an upper controller of the distributed power; set a failure confirmation count to 0; control injection of reactive power during a preset cycle among predetermined cycles of an AC voltage that is an output of the distributed power according to the failure confirmation count; measure a frequency and angular frequency of the AC voltage, which is performed simultaneously with the injection of reactive power; and after the injection of reactive power is completed, increase the failure confirmation count if a determination criteria based on the measurement of the frequency and the angular frequency of the AC voltage; after increase of the failure confirmation count is performed, determine an islanding failure when the failure confirmation count reaches a preset value, wherein the injection of the reactive power, the measurement of the frequency and the angular frequency of the AC voltage, and increase of the failure confirmation count are repeatedly performed until the islanding failure is confirmed.

In the calculation of the amount of reactive power injection, the processor may be further configured to: receive the active power command and reactive power command from the upper controller, measuring an instantaneous value of the AC voltage at a connection point between the grid and the distributed power using a voltage measurement circuit included in the distributed power, and calculating an effective value and frequency of the AC voltage using the instantaneous value; calculate a resistance value of the load using active power output from the distributed power; calculate an inductor value and capacitor value of the load using a preset power quality coefficient; and determine the amount of the reactive power injection using the effective value of the AC voltage, the inductor value, the capacitor value, and a magnitude of injection frequency.

The processor may be further configured to: inject the reactive power during m cycles among n cycles of the AC voltage; and as the failure confirmation count increases, change the m and the n so that a value obtained by dividing the m by the n increases.

In the measurement of frequency and the angular frequency of the AC voltage, the processor may be further configured to: measure the angular frequency by measuring an output of PLL included in the distributed power.

### BRIEF DESCRIPTION OF THE DRAWINGS

FIG. 1 is a diagram schematically illustrating a power system to which an islanding determination method is applied in a disturbance and distortion system according to an embodiment of the disclosure.

FIG. 2 is a block diagram of active power and reactive power control in an islanding determination method in a disturbance and distortion system according to an embodiment of the disclosure.

FIG. 3 is a flowchart of an islanding determination method in a disturbance and distortion system according to an embodiment of the disclosure.

FIG. 4 is a detailed flowchart of step a) in an islanding determination method in a disturbance and distortion system according to an embodiment of the disclosure.

FIG. 5 is a block diagram of SRF-PLL which is a PLL used in an islanding determination method in a disturbance and distortion system according to an embodiment of the disclosure.

FIG. 6 is a graph of reactive power, frequency of AC voltage, angular frequency as output value of PLL, and failure confirmation count while applying an islanding determination method in a disturbance and distortion system according to an embodiment of the disclosure.

### DETAILED DESCRIPTION

The aforementioned objects, features, and advantages of the disclosure will be clearer through the following embodiment associated with the accompanying drawings. The following specific structure or functional explanations are illustrated to describe embodiments in accordance with the concept of the disclosure. The embodiments in accordance with the concept of the disclosure may be embodied in various forms but are not interpreted to be limited to the embodiments described in this specification or application. Various modifications and changes may be applied to the embodiments in accordance with the concept of the disclosure and the embodiments may have various forms so that the specific embodiments will be described in detail in the specification or the application with reference to the drawings. However, this does not limit the disclosure within specific exemplary embodiments, and it should be understood that the disclosure covers all the modifications, equivalents and replacements within the spirit and technical scope of the disclosure. Terms such as first or second may be used to describe various components but the components are not limited by the above terminologies. The above terminologies are used to distinguish one component from the other component, for example, a first component may be referred to as a second component without departing from a scope in accordance with the concept of the disclosure and similarly, a second component may be referred to as a first component. It should be understood that, when it is described that an element is coupled or connected to another element, the element may be directly coupled or directly connected to the other element or coupled or connected to the other element through a third element. On the contrary, it should be understood that when an element is referred to as being directly connected to or directly coupled to another element, another element does not intervene therebetween. Other expressions to describe the relationship between elements, that is, expressions such as “between”, “immediately between”, “adjacent to”, or “directly adjacent to” need to be also similarly interpreted. Terms used in the specification are used only to describe specific embodiments, and are not intended to limit the disclosure. A singular form may include a plural form if there is no clearly opposite meaning in the context. In the specification, it should be understood that the term “include” or “have” indicates that a feature, a number, a step, an operation, a component, a part or the combination thereof described in the specification is present, but does not exclude a possibility of presence or addition of one or more other features, numbers, steps, operations, components, parts or combinations thereof, in advance. If it is not contrarily defined, all terms used herein including technological or scientific terms have the same meaning as those generally understood by a person with ordinary skill in the art. Terms which are defined in a generally used dictionary should be interpreted to have the same meaning as the meaning in the context of the related art but are not interpreted as an ideally or excessively formal meaning if it is not clearly defined in this specification. Hereinafter, embodiments of the disclosure will be described in detail with reference to the accompanying drawings. The same reference numerals indicated in respective drawings will be employed as those for representing the same members.

The disclosure relates to a method for detecting an islanding of a distributed power in a power system in which a grid and distributed power supply power to loads. Here, the distributed power may be various types of renewable energy generation devices or on board charger (OBC) of electric vehicles operating in vehicle to grid (V2G).

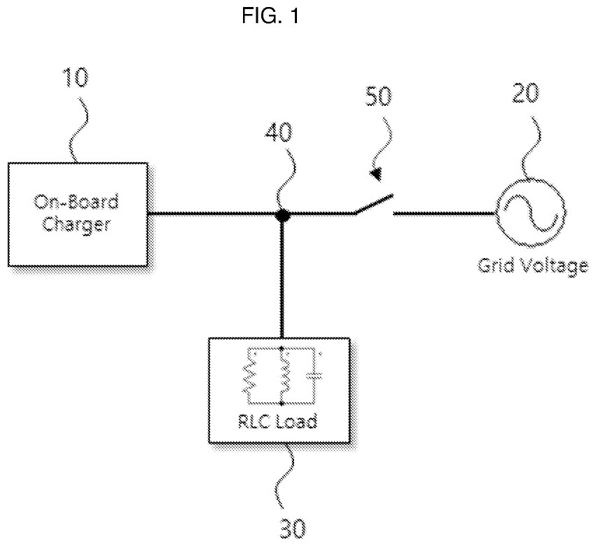

FIG. 1 is a diagram schematically illustrating a power system to which an islanding determination method is applied in a disturbance and distortion system according to an embodiment of the disclosure.

As illustrated in FIG. 1, an OBC 10 and a grid 20 may supply power to a load 30, and the load 30 may be connected to a point common coupling (PCC) 40 located between the OBC 10 and the grid 20, and a recloser 50 may be located between the PCC 40 and the grid 20.

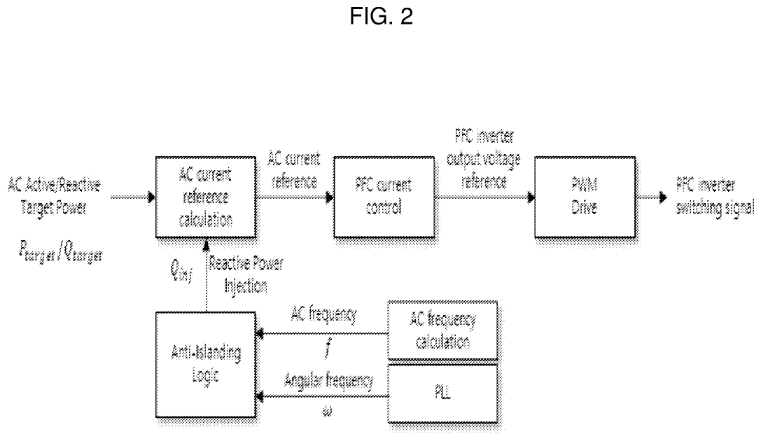

FIG. 2 is a block diagram of active power and reactive power control in an islanding determination method in a disturbance and distortion system according to an embodiment of the disclosure.

As illustrated in FIG. 2, an AC current command calculation logic uses the active power and reactive power commands received from an upper controller outside a charger and the reactive power, which is an output value of an islanding prevention logic that performs the algorithm of the disclosure, to calculate an AC current command. A PFC inverter current controller calculates a PFC inverter voltage command to control the current according to the calculated current command and sends a switching signal by a PWM output logic.

The block diagram illustrated in FIG. 2 may be controlled by a controller that controls the OBC 10. Here, the controller may be implemented with various devices included in the OBC 10, for example, an electronic device or an apparatus including an electronic device, which may receive measured values or signals from a device such as the PLL illustrated in FIG. 2 and control the OBC 10 based on the received signals.

Referring to FIG. 2, when the OBC 10 operates in V2G mode, after receiving the active power command P_{target} and reactive power command Q_{target} received from the upper controller of an electric vehicle, reactive power is injected according to the received P_{target} and Q_{target}. It is determined whether to operate islanding based on the frequency change rate, angular frequency change amount, and frequency change amount according to the injected reactive power. The method includes steps a) to e) sequentially performed by the above-described controller.

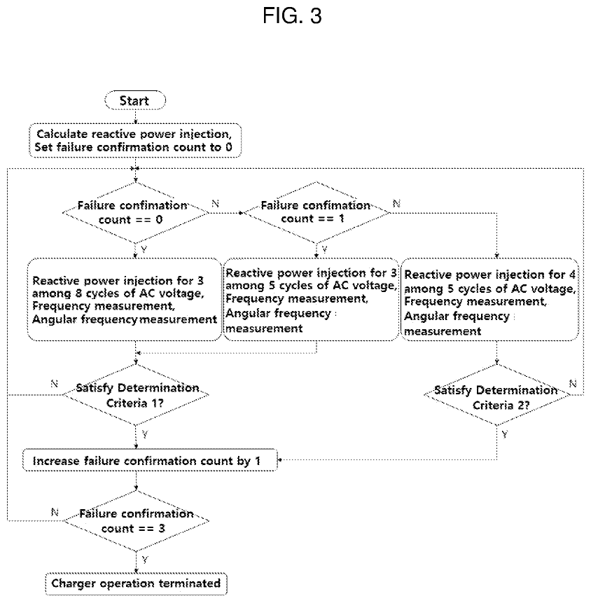

FIG. 3 is a flowchart of an islanding determination method in a disturbance and distortion system according to an embodiment of the disclosure.

Referring to FIG. 3, step a) calculates an amount of reactive power injection Qᵢₙⱼ based on the distributed power, that is, P_{target} and Q_{target} received from the upper controller of the OBC 10, and sets a failure confirmation count to 0. Step a) described above includes steps a-1) to a-4) that are performed sequentially.

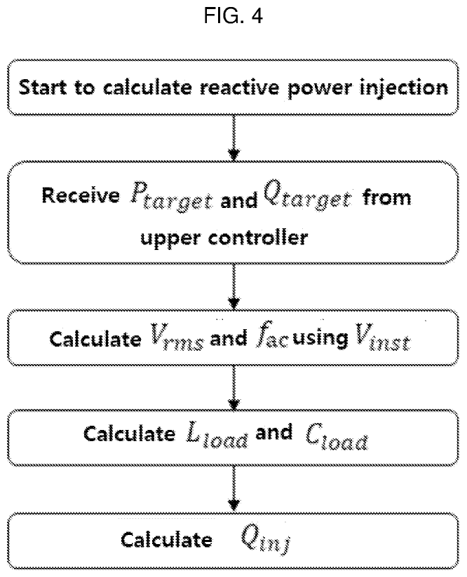

FIG. 4 is a detailed flowchart of step a) in an islanding determination method in a disturbance and distortion system according to an embodiment of the disclosure.

Referring to FIG. 4, in step a-1), the controller measures Vᵢₙₛₜ, which is an instantaneous value in the PCC 40, using a voltage measurement circuit included in the OBC 10 or electric vehicle side, and uses Vᵢₙₛₜ to calculate the effective value Vᵣₘₛ and frequency f_{grid} of an AC voltage, which is the output voltage of the OBC 10. A known method is used to calculate Vᵣₘₛ and f_{grid} using instantaneous values. Briefly, the instantaneous value Vᵢₙₛₜ is converted from a time domain to a periodic function in a frequency domain using frequency analysis or Fourier transform. Afterwards, the controller identifies the frequency component of the voltage in the frequency domain. Generally, the controller selects the largest frequency component and calculates the frequency based on the selected frequency component. The controller uses voltage data corresponding to the selected frequency component to calculate the effective value Vᵣₘₛ. More specifically, the controller may square the voltage data for the selected frequency component to obtain an average, and then obtain the effective value Vᵣₘₛ through the square root.

Step a-1) described above is repeatedly performed for each cycle of the AC voltage, which is the output voltage of the OBC 10, so that the effective value and frequency may be repeatedly calculated.

Referring to FIG. 4, in step a-2), the controller calculates the resistance value of the load 30 using the active power output from the OBC 10. Referring to FIG. 1, when the recloser 50 is opened, the OBC 10 is independently connected to the RLC load 30 to supply power. In this case, using the active power supplied to the load 30, R_{load} which is the resistance value of the load 30, may be obtained, and the equation for calculating R_{load} is as follows.

$${R}_{load} = \frac{{V}_{rms}^{2}}{{P}_{target}} \qquad [ Equation 1 ]$$

Referring to FIG. 4, in step a-3), the controller calculates the inductor values of the load 30, L_{load} and C_{load}, using Q_{f}, which is a preset power quality coefficient.

To calculate L_{load} and C_{load} in step a-3), the controller may use Equations 2 and 3 below.

$${f}_{grid} = 2 π \frac{1}{\sqrt{{L}_{load} {C}_{load}}} \qquad [ Equation 2 ]$$

$${Q}_{f} = {R}_{load} \sqrt{\frac{{C}_{Load}}{{L}_{Load}}} \\ {L}_{Load} = \frac{{R}_{load}}{2 π {f}_{grid} {Q}_{f}} \\ {C}_{Load} = \frac{{Q}_{f}}{2 π {f}_{grid} {R}_{load}} \qquad [ Equation 3 ]$$

In Equation 2 and Equation 3 above, f_{grid}, Q_{f} and R_{load} are already known values, and in step a-3), the controller calculates L_{load} and C_{load} using the above equation.

In step a-4), the controller calculates an amount of reactive power injection Qᵢₙⱼ using the effective value of the AC voltage Vᵣₘₛ, an inductor value L_{load}, a capacitor value C_{load}, and the magnitude of injection frequency fᵢₙⱼ. The controller may calculate Q_{inf} using the equation below.

$${Q}_{inj} = {V}_{rms}^{2} * ( \frac{1}{2 π {f}_{inj} {L}_{load}} - 2 π {f}_{inj} {C}_{load} ) \qquad [ Equation 4 ]$$

In the above equation, the magnitude of injection frequency, fᵢₙⱼ may be calculated using the equation below.

$${f}_{inj} = {f}_{grid} + Δ {f}_{inj} \qquad [ Equation 5 ]$$

As can be seen from Equation 5 above, the injection frequency fᵢₙⱼ may be obtained by adding the injection frequency increment Δfᵢₙⱼ to the frequency f_{grid} of the system 20. Here, the injection frequency increment Δfᵢₙⱼ can be determined through the equation below.

$$- {Q}_{acc} * {Q}_{rated} < {Q}_{inj} < + {Q}_{acc} * {Q}_{rated} \qquad [ Equation 6 ]$$

In Equation 6 above, Q_{acc} is the preset reactive power accuracy, and Q_{rated} is the rated reactive power of the distributed power. After substituting Equation 5 into Equation 4, and then substituting the defined Qᵢₙⱼ in Equation 4 into Equation 6, the defined Qᵢₙⱼ including Δf ᵢₙⱼ is determined to be within a predetermined range. When Equation 5 is substituted into Equation 4, there are only variable Δfᵢₙⱼ on the right side, so in Equation 6, Δf ᵢₙⱼ is determined to be within a specific range.

In step b), according to the failure confirmation count, reactive power is injected by the size of the reactive power Qᵢₙⱼ calculated in step a) during a preset cycle of preset cycles of the AC voltage. Since the failure confirmation count is set to 0 in step a) described above, in this embodiment, the controller injects reactive power for 3 of the 8 cycles of the AC voltage. Additionally, in step b), reactive power is injected so that plus and minus directions appear alternately.

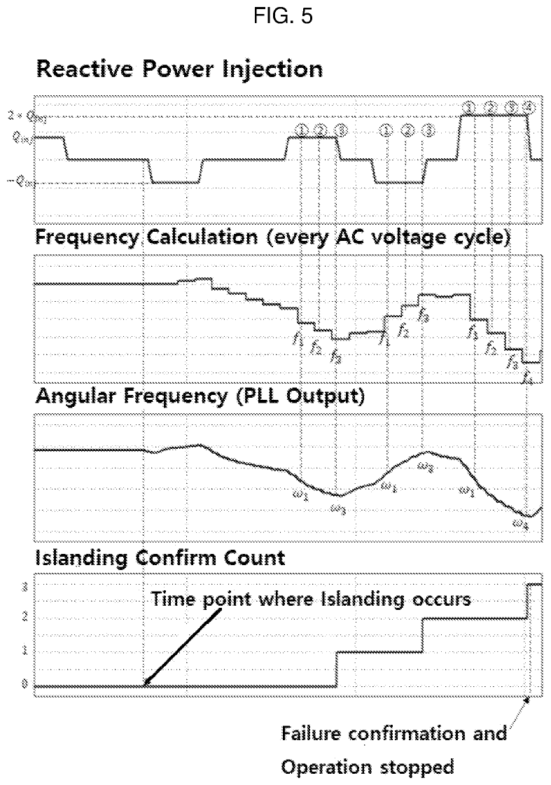

Step c) is performed simultaneously with step b), and in step c), the controller measures the frequency and angular frequency of the AC voltage. Here, the angular frequency may be the output value of the PLL included in the OBC 10 according to this embodiment. FIG. 5 is a block diagram of SRF-PLL which is a PLL used in an islanding determination method in a disturbance and distortion system according to an embodiment of the disclosure.

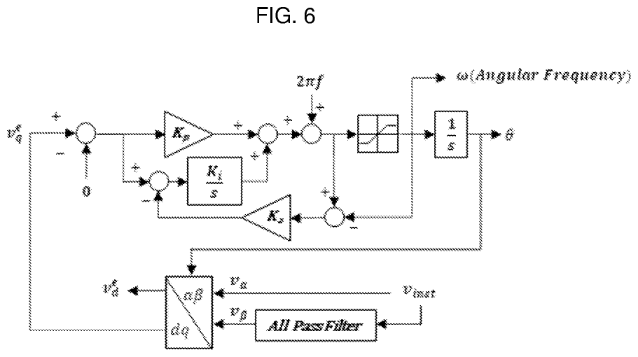

FIG. 6 is a graph of reactive power, frequency of AC voltage, angular frequency as output value of PLL, and failure confirmation count while applying an islanding determination method in a disturbance and distortion system according to an embodiment of the disclosure.

Referring to FIG. 6, when the controller injects reactive power in step b), the reactive power is injected in forms of a first section in which the reactive power increases linearly to a target value, a second section in which the reactive power value is maintained, and a third section in which the reactive power decreases linearly. In other words, reactive power is injected in a kind of trapezoidal shape.

In step c), if the fault confirmation count is 0 or 1, the controller measures the frequencies at three points in the second section where reactive power is maintained, and these frequencies are called f₁, f₂, f₃. Based on the time point, the frequency with the smaller subscript is the frequency measured first. Among the above frequencies, f₁ may be a frequency measured at the end of the second section and the start of the third section. Also, in step c), if the failure confirmation count is 0 or 1, each frequency is measured at the first and last time points among the three time points when the frequency has been measured. ω₁ and ω₃ refer to the angular frequencies measured at the first and last time points in order, respectively. The above ω₃ may be an angular frequency measured at the end of the second section and the start of the third section.

In step c), if the failure confirmation count is 2, the controller measures the frequency at each of the four points in the second section where reactive power is maintained, and these frequencies are referred to as f₁, f₂, f₃, f₄. Based on the time point, the frequency with the smaller subscript is the frequency measured first. Among the above frequencies, f₄ may be a frequency measured at the end of the second section and the start of the third section. Also, in step c), if the failure confirmation count is 2, each frequency is measured at the first and last time points among the four time points when the frequency has been measured. ω₁ and ω₄ refer to the angular frequencies measured at the first and last time points in order, respectively. The above ω₄ may be an angular frequency measured at the end of the second section and the start of the third section.

In step d), after step b) is completed, the controller increases the failure confirmation count according to a predetermined criterion based on the frequency and angular frequency measured in step c) and the failure confirmation count. More specifically, when the failure confirmation count is 0 or 1, in step d), the controller increases the failure confirmation count by 1 if all of the following determination criteria are satisfied, and maintains the failure confirmation count if all of the following determination criteria are not satisfied.

$$\vert {ω}_{1} - {ω}_{3} \vert \geq \vert 2 π Δ {f}_{inj} \vert \\ ( {f}_{1} < {f}_{2} < {f}_{3} ) ‖ ( {f}_{1} > {f}_{2} > {f}_{3} ) \qquad [ Determination Criteria 1 ]$$

The condition in the second line of Determination Criteria 1 above means the ‘or’ condition.

In step d), when the failure confirmation count is 2, the controller increases the failure confirmation count by 1 if all of the following determination criteria are satisfied, and maintains the failure confirmation count if all of the following judgment criteria are not satisfied.

$$\vert {ω}_{1} - {ω}_{4} \vert \geq \vert 2 π Δ {f}_{inj} \vert \\ ( {f}_{1} < {f}_{2} < {f}_{3} < {f}_{4} ) ‖ ( {f}_{1} > {f}_{2} > {f}_{3} > {f}_{4} ) \\ \vert {f}_{1} - {f}_{4} \vert \geq Δ {f}_{inj} \qquad [ Determination Criteria 2 ]$$

In step e), the controller determines an islanding failure when the failure confirmation count reaches a preset value after step d) is performed. In this embodiment, the preset value may be 3.

Steps b) to e) may be repeatedly performed until the controller determines the islanding failure in step e).

In the above step b), it is described that the controller injects reactive power for 3 out of 8 cycles of the AC voltage when the failure confirmation count is 0. In addition, in step b), the controller injects reactive power for 3 out of 5 cycles of the AC voltage when the failure confirmation count is 1, and injects reactive power for 4 out of 5 cycles of the AC voltage when the failure confirmation count is 2. However, injecting reactive power for several cycles among predetermined cycles of the AC voltage according to the failure confirmation count is only one embodiment, and the values of preset cycle of the AC voltage and cycle of injecting the reactive power may vary. However, in step b) of the disclosure, when reactive power is injected during m cycles out of n cycles of AC voltage, the value obtained by dividing n by m, that is, the proportion of cycles injecting reactive power among the total cycles of AC voltage may increase as the failure confirmation count increases (m is a natural number less than or equal to n). One or more processors or controllers may be configured to control or actuate the steps above.

According to the disclosure as described above, there is no false detection even in sections where harmonics exist in the system, and the amount of reactive power injection can be calculated in real time through an equation using the active power and reactive power control commands from the upper controller. Therefore, even if the active power command and reactive power command change, islanding can be determined within a certain time.

According to the islanding determination method in a disturbance and distortion system according to the disclosure as described above, no false detection is made even in sections where harmonics exist in the system, and the amount of reactive power injection is calculated using the active power and reactive power control commands of the upper controller. Thus, it has the effect of being able to determine the islanding within a certain time even if the active power command and reactive power command change.

Although preferred embodiments of the disclosure have been described above, the embodiments disclosed in the disclosure are not intended to limit the technical idea of the disclosure but are only for explanation. Accordingly, the technical idea of the disclosure includes not only each disclosed embodiment, but also a combination of the disclosed embodiments, and furthermore, the scope of the technical idea of the disclosure is not limited by these embodiments. Also, it will be apparent to those having ordinary skill in the art that a number of changes, modifications, or alterations to the invention as described herein may be made, none of which depart from the spirit of the disclosure. All such changes, modifications, alterations, and equivalents should therefore be seen as within the scope of the present invention.

What is claimed is:

1. A method for determining islanding of a system in which a grid and distributed power supply power to a load, the method comprising the steps of:
a) calculating an amount of reactive power injection based on an active power command and reactive power command received from an upper controller of the distributed power, and setting a failure confirmation count to 0;
b) injecting reactive power during a preset cycle among predetermined cycles of an AC voltage that is an output of the distributed power according to the failure confirmation count;
c) measuring a frequency and angular frequency of the AC voltage, which is performed simultaneously with the step b);
d), after the step b) is completed, increasing the failure confirmation count if a determination criteria based on the frequency and angular frequency measured in the step c) is satisfied; and
e), after the step d) is performed, determining an islanding failure when the failure confirmation count reaches a preset value,
wherein the step b), the step c), the step d), and the step e) are repeatedly performed until the islanding failure is confirmed in the step e).

2. The method of claim 1, wherein the step a) comprises the steps of:
a-1) receiving the active power command and reactive power command from the upper controller, measuring an instantaneous value of the AC voltage at a connection point between the grid and the distributed power using a voltage measurement circuit included in the distributed power, and calculating an effective value and frequency of the AC voltage using the instantaneous value;
a-2) calculating a resistance value of the load using active power output from the distributed power;
a-3) calculating an inductor value and capacitor value of the load using a preset power quality coefficient; and
a-4) determining the amount of the reactive power injection using the effective value of the AC voltage, the inductor value, the capacitor value, and a magnitude of injection frequency.

3. The method of claim 2, wherein in the step a-1), the effective value and frequency of the AC voltage are repeatedly calculated at regular cycles using the instantaneous value.

4. The method of claim 2, wherein in the step a-4), the amount of the reactive power injection is calculated using an equation below:
$${Q}_{inj} = {V}_{rms}^{2} * ( \frac{1}{2 π {f}_{inj} {L}_{load}} - 2 π {f}_{inj} {C}_{load} )$$
where, Qᵢₙⱼ is the amount of the reactive power injection, Vᵣₘₛ is the effective value of the AC voltage, fᵢₙⱼ is the magnitude of the injection frequency, L_{load} is the inductor value of the load, and C_{load} is the capacitor value of the load.

5. The method of claim 4, wherein the step a-4) determines the magnitude of the injection frequency using an equation below:
$${f}_{inj} = {f}_{grid} + Δ {f}_{inj} - {Q}_{acc} * {Q}_{rated} < {Q}_{inj} < + {Q}_{acc} * {Q}_{rated} \\ {f}_{grid} = 2 π \frac{1}{\sqrt{{L}_{load} {C}_{load}}}$$
where, f_{grid} is a frequency of the grid, Δfᵢₙⱼ is an increment of the injection frequency, Q_{acc} is a preset reactive power accuracy, and Q_{rated} is a rated reactive power of the distributed power.

6. The method of claim 1, wherein in the step b), the reactive power is injected during m cycles among n cycles of the AC voltage, and as the failure confirmation count increases, the m and the n are changed so that a value obtained by dividing the m by the n increases.

7. The method of claim 6, wherein in the step b),
when the failure confirmation count is 0, the reactive power is injected for 3 cycles out of 8 cycles of the AC voltage,
when the failure confirmation count is 1, the reactive power is injected for 3 cycles out of 5 cycles of the AC voltage, and
when the failure confirmation count is 2, the reactive power is injected during 4 cycles out of 5 cycles of the AC voltage.

8. The method of claim 1, wherein the step e) comprises confirming the islanding failure when the failure confirmation count is 3.

9. The method of claim 1, wherein in the step b), the reactive power is alternately injected in plus and minus directions.

10. The method of claim 1, wherein in the step c), the angular frequency is measured by measuring an output of PLL included in the distributed power.

11. The method of claim 10,
wherein in the step b), the reactive power is injected during a first section in which the reactive power linearly increases, a second section in which the reactive power is maintained, and a third section in which the reactive power linearly decreases, and
wherein in the step c), when the failure confirmation count is 0 or 1, the frequency is measured at three time points in the second section, and the angular frequency is measured at first and last time points among the three time points.

12. The method of claim 11, wherein in the step d), if all of determination criteria below are satisfied, the failure confirmation count is increased using an equation below:
$$\vert {ω}_{1} - {ω}_{3} \vert \geq \vert 2 πΔ {f}_{inj} \vert \\ ( {f}_{1} < {f}_{2} < {f}_{3} ) ‖ ( {f}_{1} > {f}_{2} > {f}_{3} )$$
where, ω₁ is the angular frequency measured at the first time point of the three time points, w₃ is the angular frequency measured at the last time point among the three time points, f₁, f₂, f₂ are the frequencies measured sequentially at the three time points, and Δfᵢₙⱼ is an increment of the injection frequency.

13. The method of claim 10,
wherein in the step b), the reactive power is injected during a first section in which the reactive power linearly increases, a second section in which the reactive power is maintained, and a third section in which the reactive power linearly decreases,
wherein in the step c), when the failure confirmation count is 2, the frequency is measured at four time points in the second section, and the angular frequency is measured at first and last time points of the four time points, using an equation below:
$$\vert {ω}_{1} - {ω}_{4} \vert \geq \vert 2 πΔ {f}_{inj} \vert \\ ( {f}_{1} < {f}_{2} < {f}_{3} < {f}_{4} ) ‖ ( {f}_{1} > {f}_{2} > {f}_{3} > {f}_{4} ) \\ \vert {f}_{1} - {f}_{4} \vert \geq Δ {f}_{inj}$$
where ω₁ is the angular frequency measured at the first time point of the four time points, ω₄ is the angular frequency measured at the last time point among the four time points, f₁, f₂, f₃, f₄ are the frequencies measured sequentially at the four time points, and Δfᵢₙⱼ is an increment of the injection frequency.

14. An apparatus for determining islanding of a system in which a grid and distributed power supply power to a load, the apparatus comprising:
a processor configured to:
calculate an amount of reactive power injection based on an active power command and reactive power command received from an upper controller of the distributed power;
set a failure confirmation count to 0;
control injection of reactive power during a preset cycle among predetermined cycles of an AC voltage that is an output of the distributed power according to the failure confirmation count;
measure a frequency and angular frequency of the AC voltage, which is performed simultaneously with the injection of reactive power; and
after the injection of reactive power is completed, increase the failure confirmation count if a determination criteria based on the measurement of the frequency and the angular frequency of the AC voltage;
after increase of the failure confirmation count is performed, determine an islanding failure when the failure confirmation count reaches a preset value,
wherein the injection of the reactive power, the measurement of the frequency and the angular frequency of the AC voltage, and increase of the failure confirmation count are repeatedly performed until the islanding failure is confirmed.

15. The apparatus of claim 14, wherein, in the calculation of the amount of reactive power injection, the processor is further configured to:
receive the active power command and reactive power command from the upper controller, measuring an instantaneous value of the AC voltage at a connection point between the grid and the distributed power using a voltage measurement circuit included in the distributed power, and calculating an effective value and frequency of the AC voltage using the instantaneous value;
calculate a resistance value of the load using active power output from the distributed power;
calculate an inductor value and capacitor value of the load using a preset power quality coefficient; and
determine the amount of the reactive power injection using the effective value of the AC voltage, the inductor value, the capacitor value, and a magnitude of injection frequency.

16. The apparatus of claim 14, wherein the processor is further configured to:
inject the reactive power during m cycles among n cycles of the AC voltage; and
as the failure confirmation count increases, change the m and the n so that a value obtained by dividing the m by the n increases.

17. The apparatus of claim 14, wherein, in the measurement of frequency and the angular frequency of the AC voltage, the processor is further configured to:
measure the angular frequency by measuring an output of PLL included in the distributed power.
